(19) United States
(12) Patent Application Publication
(10) Pub. No.: US 2010/0178754 A1
(43) Pub. Date: Jul. 15, 2010

(54) METHOD OF MANUFACTURING CMOS TRANSISTOR

(75) Inventors: Jun-youl Yang, Seoul (KR); Byoung-moon Yoon, Suwon-si (KR); Cheol-woo Park, Seoul (KR); Won-jun Lee, Seoul (KR); Ki-hyung Ko, Seoul (KR)

Correspondence Address: MILLS & ONELLO LLP, ELEVEN BEACON STREET, SUITE 605, BOSTON, MA, 02108, US

(73) Assignee: SAMSUNG ELECTRONICS CO., LTD., Gyeonggi-do (KR)

(21) Appl. No.: 12/479,112

(22) Filed: Jun. 5, 2009

(30) Foreign Application Priority Data
Jan. 9, 2009 (KR) 10-2009-0001940

(51) Int. Cl. H01L 21/8238; H01L 21/20

(52) U.S. Cl. 438/478; 438/585; 257/E21.09; 257/E21.635

(57) ABSTRACT

A method of manufacturing a complementary metal-oxide semiconductor (CMOS) transistor includes: forming a semiconductor layer in which an n-MOS transistor region and a p-MOS transistor region are defined; forming an insulation layer on the semiconductor layer; forming a conductive layer on the insulation layer; forming a mask pattern exposing the n-MOS transistor region, on the conductive layer; generating a damage region in an upper portion of the conductive layer by implanting impurities in the conductive layer of the n-MOS transistor region using the mask pattern as a mask; removing the mask pattern; removing the damage region; and patterning the conductive layer to form an n-MOS transistor gate and a p-MOS transistor gate. Accordingly, gate thinning and formation of a step between the n-MOS transistor region gate and the p-MOS transistor region gate can be prevented.

### CROSS-REFERENCE TO RELATED APPLICATIONS

This application claims the benefit of Korean Patent Application No. 10-2009-0001940, filed on Jan. 9, 2009, in the Korean Intellectual Property Office, the entire contents of which are incorporated herein by reference.

### BACKGROUND

The inventive concept relates to a method of manufacturing a semiconductor device, and more particularly, to a method of manufacturing a complementary metal-oxide semiconductor (CMOS) transistor.

Recently, high integration degree and high operational speed are required for CMOS transistors, and thus the thickness of a polysilicon layer used as a gate in the CMOS transistors is reduced. Accordingly, the significance of the depletion of the polysilicon layer has also increased. In logic devices that require high operational speed, in particular, a dose of ions implanted into a polysilicon layer used in an n-MOS transistor, is increasing. Thus, due to the high dose of implanted impurities, the polysilicon layer may include a damage region, and gate thinning, in which gates become thin due to subsequent processes of the method of manufacturing a semiconductor device, is likely to occur.

### SUMMARY

According to an aspect of the inventive concept, there is provided a method of manufacturing a complementary metal-oxide semiconductor (CMOS) transistor, the method including: forming a semiconductor layer in which an n-MOS transistor region and a p-MOS transistor region are defined; forming an insulation layer on the semiconductor layer; forming a conductive layer on the insulation layer; forming a mask pattern exposing the n-MOS transistor region, on the conductive layer; implanting impurities in the conductive layer of the n-MOS transistor region using the mask pattern as a mask to form a damage region in an upper portion of the conductive layer; removing the mask pattern; removing the damage region; and patterning the conductive layer to form an n-MOS transistor gate and a p-MOS transistor gate.

In some embodiments of the inventive concept, in the removing of the damage region, the damage region may removed so that the conductive layer in the n-MOS transistor region has the same height as the conductive layer in the p-MOS transistor region.

In some embodiments of the inventive concept, the removing of the damage region may be performed using a mixed solution including ammonium hydroxide (NH₄OH), hydrogen peroxide (H₂O₂), and pure water (H₂O). The mixed solution may contain ammonium hydroxide (NH₄OH) in a range of 0.1 to 15 wt % and hydrogen peroxide (H₂O₂) in a range of 0.1 to 15 wt %.

In some embodiments of the inventive concept, the removing of the damage region may be performed at a temperature range of 50° C. to 90° C.

In some embodiments of the inventive concept, the conductive layer may include polysilicon.

In some embodiments of the inventive concept, after forming the n-MOS transistor gate and the p-MOS transistor gate, the method may further include washing the semiconductor layer on which the n-MOS transistor gate and the p-MOS transistor gate are formed using a washing solution having a fluoric acid.

In some embodiments of the inventive concept, before forming the n-MOS transistor gate and the p-MOS transistor gate, the method may further include forming an anti-reflection layer on the conductive layer.

In some embodiments of the inventive concept, after forming the conductive layer on the insulation layer, the method may further include forming a buffer insulation layer on the conductive layer.

According to an aspect of the inventive concept, there is provided a method of manufacturing a complementary metal-oxide semiconductor (CMOS) transistor, the method including: forming a semiconductor layer in which an n-MOS transistor region and a p-MOS transistor region are defined; forming an insulation layer on the semiconductor layer; forming a conductive layer on the insulation layer; forming a buffer insulation layer on the conductive layer; forming a mask pattern exposing the n-MOS transistor region, on the conductive layer; implanting impurities in the conductive layer of the n-MOS transistor region using the mask pattern as a mask to form a damage region in an upper portion of the conductive layer; removing the mask pattern and the buffer insulation layer; removing the damage region; forming an anti-reflection layer on the conductive layer; and patterning the conductive layer to form an n-MOS transistor gate and a p-MOS transistor gate.

### BRIEF DESCRIPTION OF THE DRAWINGS

The foregoing and other features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIGS. 1 through 6 are cross-sectional views illustrating a method of manufacturing a complementary metal-oxide semiconductor (CMOS) transistor, according to an embodiment of the inventive concept.

### DETAILED DESCRIPTION OF THE EMBODIMENTS

Reference will now be made in detail to exemplary embodiments, examples of which are illustrated in the accompanying drawings. However, exemplary embodiments are not limited to the embodiments illustrated hereinafter.

It will be understood that when an element, such as a layer, a region, or a substrate, is referred to as being “on,” “connected to” or “coupled to” another element, it may be directly on, connected or coupled to the other element or intervening elements may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of exemplary embodiments.

Spatially relative terms, such as “above,” “upper,” “beneath,” “below,” “lower,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “above” may encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. It will be further understood that the terms “comprises” and/or “comprising” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but may be to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes may be not intended to illustrate the actual shape of a region of a device and are not intended to limit the scope of exemplary embodiments.

Unless otherwise defined, all terms (including technical and scientific terms) used herein have the same meaning as commonly understood by one of ordinary skill in the art to which exemplary embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the exemplary embodiments of the inventive concept will be described in detail with reference to the accompanying drawings. In the drawings, variations from the shapes of the illustrations as a result, for example, of manufacturing techniques and/or tolerances, are to be expected. Thus, the examplary embodiments should not be construed as limited to the particular shapes of regions illustrated herein but may be to include deviations in shapes that result, for example, from manufacturing.

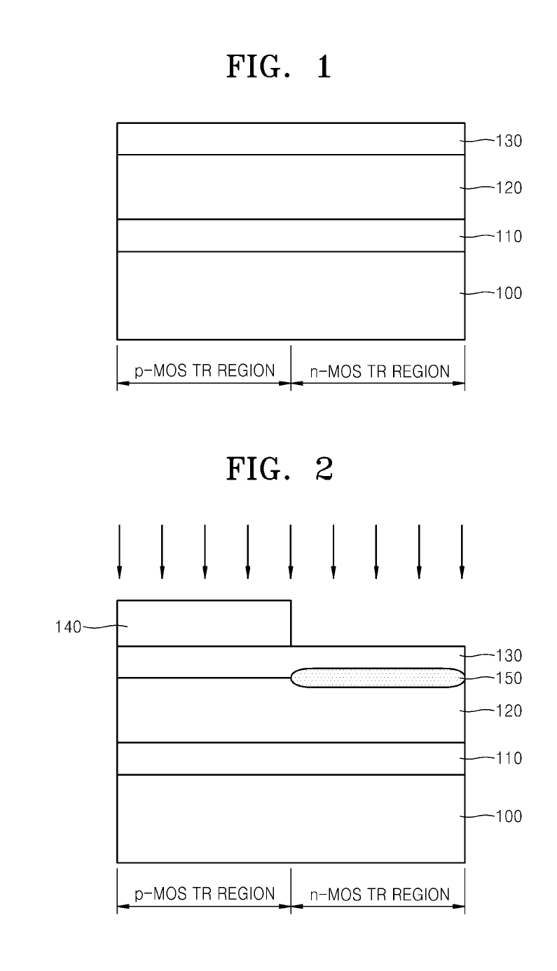

FIGS. 1 through 6 are cross-sectional views illustrating a method of manufacturing a complementary metal-oxide semiconductor (CMOS) transistor, according to an embodiment of the inventive concept.

Referring to FIG. 1, a semiconductor layer 100 is prepared. In the semiconductor layer 100, an n-MOS transistor region for forming an n-MOS transistor and a p-MOS transistor region for forming a p-MOS transistor are defined. The semiconductor layer 100 may include a substrate including a semiconductor material such as silicon, silicon-germanium, etc., an epitaxial layer, a silicon-on-insulator (SOI) layer, and/or a semiconductor-on-insulator (SEOI) layer. Also, the semiconductor layer 100 may include a p-well, an n-well, or a device isolation layer.

An insulation layer 110 is disposed on the semiconductor layer 100. The insulation layer 110 may function as a gate insulation layer and may include an oxide, a nitride, an oxinitride, or a combination thereof. A conductive layer 120 is disposed on the insulation layer 110. The conductive layer 120 may function as a gate electrode and may include, for example, polysilicon. The conductive layer 120 may have a height of about 1000 Å to about 3000 Å.

A buffer insulation layer 130 is optionally disposed on the conductive layer 120. The buffer insulation layer 130 may protect the conductive layer 120 from external influences or prevent the conductive layer 120 from being consumed during subsequent processes of the method of manufacturing a CMOS transistor. The buffer insulation layer 130 may include an oxide, a nitride, an oxinitride, or a combination thereof. The insulation layer 110, the conductive layer 120, and the buffer insulation layer 130 may be formed using typical deposition methods such as a chemical vapor deposition (CVD) method, a plasma enhanced CVD (PECVD) method, an atomic layer deposition (ALD) method, a sputtering method, or any other modified deposition method thereof.

Referring to FIG. 2, a mask pattern 140 which exposes the n-MOS transistor region is formed on the conductive layer 120 or the buffer insulation layer 130. The mask pattern 140 may be a typical photoresist pattern or a hard mask pattern such as a silicon nitride layer or a silicon oxinitride layer. Next, the conductive layer 120 of the exposed n-MOS transistor region is implanted with a required amount of impurities, for example, n-type impurities, using the mask pattern 140 as a mask. Examples of the n-type impurities include phosphor (P), arsenic (As), and antimony (Sn). The implanted n-type impurities may improve the current characteristics of a gate of an n-MOS transistor. Here, since a dose of the n-type implanted impurities in the conductive layer 120 of the n-MOS transistor region is high, a damage region 150 is formed in an upper portion of the conductive layer 120 of the n-MOS transistor region even when the buffer insulation layer 130 is formed. The height of the damage region 150 may vary according to the dose of the implanted n-type impurities, the implantation energy, and the implantation depth. The height of the damage region 150 may be, for example, about 100 Å to about 500 Å.

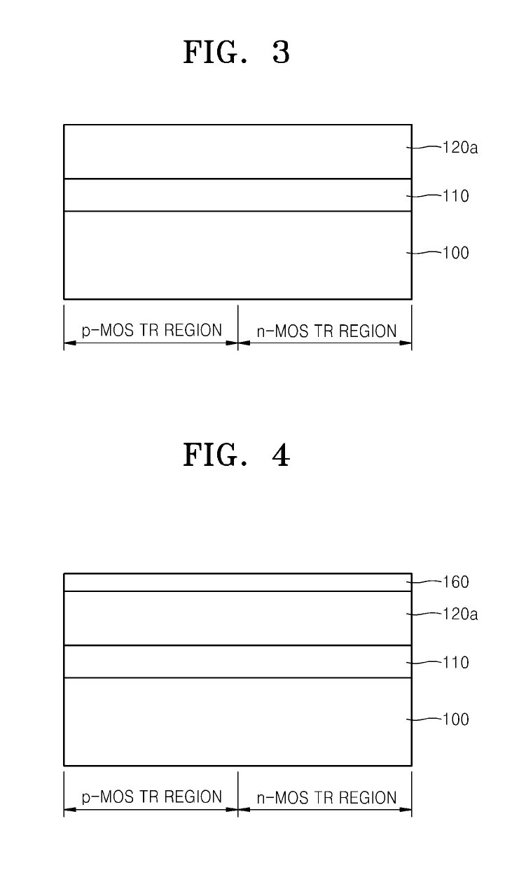

Referring to FIG. 3, the mask pattern 140 and the buffer insulation layer 130 are removed using, for example a conventional method. Then, the damage region 150 is removed. The damage region 150 may be removed using a solution including ammonium hydroxide (NH₄OH), such as a mixed solution including ammonium hydroxide (NH₄OH), hydrogen peroxide (H₂O₂), and pure water (H₂O). The mixed solution may contain ammonium hydroxide (NH₄OH) in a range of about 0.1 to about 15 wt % and hydrogen peroxide (H₂O₂) in a range of about 0.1 to about 15 wt %. A residual of the mixed solution may be pure water (H₂O). The mixed solution may be a general SC-1 solution (ammonium hydroxide: hydrogen peroxide: pure water=4:1:95), but is not limited thereto. Also, the damage region 150 may be removed at a temperature range of 50° C. to 90° C., for example, at a temperature range of 70° C. to 80° C. The height at which the conductive layer 120 is removed using the mixed solution may be at least equal to the height of the above-described damage region 150. For example, the height may be about 100 Å to about 500 Å. Alternatively, the damage region 150 may be removed by conducting a chemical mechanical polishing (CMP) method using the mixed solution.

When removing the damage region 150, the damage region 150 may be removed in the n-MOS transistor region using the mixed solution, and a portion of the conductive layer 120 may be removed in the p-MOS transistor region so that the height of the conductive layer 120 corresponds to the height of the damage region 150. Accordingly, the height of a conductive layer 120a in the n-MOS transistor region has the same as the height of a conductive layer 120a in the p-MOS transistor region. That is, a step may not be formed between the conductive layer 120a in the n-MOS transistor region and the p-MOS transistor region.

Also, after the impurities are implanted, and before or after removing the damage region 150, a heat treatment for diffusing n-type impurities in the conductive layer 120a of the n-MOS transistor region may be optionally performed.

Referring to FIG. 4, an anti-reflection layer 160 is disposed on the conductive layer 120a. The anti-reflection layer 160 is used when etching the gate of the n-MOS transistor or the p-MOS transistor, and may include silicon oxinitride (SiON) or silicon nitride (SiN). The anti-reflection layer 160 may be formed using, for example a typical deposition method such as a chemical vapor deposition (CVD) method, a plasma enhanced CVD (PECVD) method, an atomic layer deposition (ALD) method, a sputtering method, or any other modified deposition method thereof. Also, the anti-reflection layer 160 may be formed using a thermal process, a rapid thermal annealing (RTA) method, or a coating method.

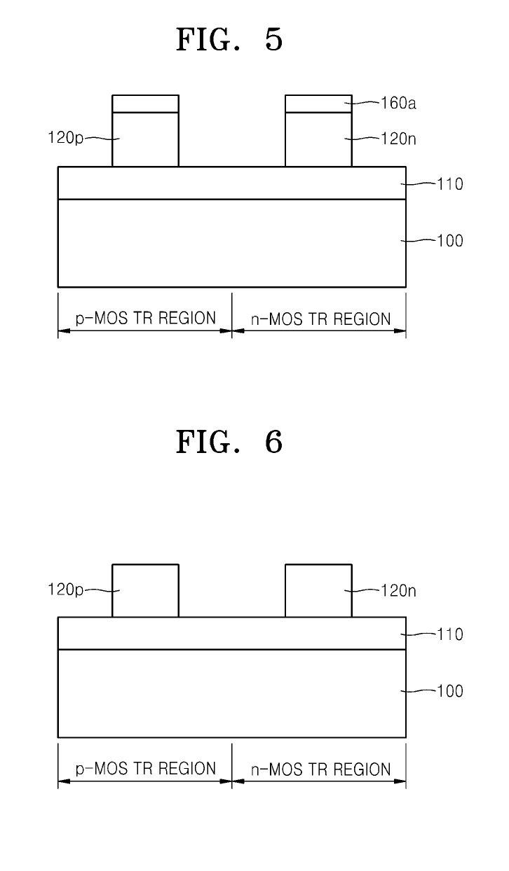

Referring to FIG. 5, a mask pattern (not shown) is formed on the semiconductor layer 100 after the implantation process for forming the gate of the n-MOS transistor is performed. Next, etching is performed using the mask pattern as a mask, and accordingly, an anti-reflection layer pattern 160a, a p-MOS transistor gate pattern 120p, and an n-MOS transistor gate pattern 120n are formed. The etching may be a typical wet etching method or a dry etching method. When a dry etching method is used, mixed gas of HBr, Cl₂, O₂, HeO₂, and N₂ may be used.

Referring to FIG. 6, the semiconductor layer 100 on which the n-MOS transistor gate pattern 120n and the p-MOS transistor gate pattern 120p are formed is washed using a washing solution including a fluoric acid. During the washing operation, the anti-reflection layer pattern 160a may be removed. The washing solution may further include hydrogen peroxide (H₂O₂) and pure water (H₂O). The dilution rate of the fluoric acid in the entire washing solution may be about ⅕ to about 1/2000. Alternatively, the semiconductor layer 100 may be washed using a dry washing method using plasma. For example, the dry washing method may be conducted at a pressure of about 500 mTorr to about 2000 mTorr, at a power of about 500 W to about 3000 W, and under an argon (Ar) atmosphere. Next, although not illustrated, subsequent processes of the method of manufacturing a CMOS transistor are conducted to complete a structure of the n-MOS transistor and the p-MOS transistor.

As described above, while the current embodiment is described with respect to the n-MOS transistor region, the inventive concept is not limited thereto. That is, the inventive concept may also be applied to a case in which a damage region is formed in a conductive layer of the p-MOS transistor region due to ion implantation. When the inventive concept is applied to the p-MOS transistor region, the types of implantation ions such as boron (B), aluminum (Al), gallium (Ga), or indium (In), the process conditions such as the type and density of a solution for removing the damage region, the temperature, the height of the damage region being removed, and so forth, may vary, which is obvious to one of ordinary skill in the art.

In addition, as described above, a transistor manufactured according to the embodiments of the inventive concept may be applied to dynamic random access memories (DRAM), static random access memories (SRAM), non-volatile memory devices, logic devices, and so forth.

The foregoing is illustrative of exemplary embodiments and is not to be construed as limiting thereof. Although exemplary embodiments have been described, those of ordinary skill in the art will readily appreciate that many modifications are possible in the exemplary embodiments without materially departing from the novel teachings and advantages of the exemplary embodiments. Accordingly, all such modifications are intended to be included within the scope of the claims. Exemplary embodiments are defined by the following claims, with equivalents of the claims to be included therein.

What is claimed is:

1. A method of manufacturing a complementary metal-oxide semiconductor (CMOS) transistor, the method comprising:
forming a semiconductor layer in which an n-MOS transistor region and a p-MOS transistor region are defined;
forming an insulation layer on the semiconductor layer;
forming a conductive layer on the insulation layer;
forming a mask pattern exposing the n-MOS transistor region, on the conductive layer;
implanting impurities in the conductive layer of the n-MOS transistor region using the mask pattern as a mask to form a damage region in an upper portion of the conductive layer;
removing the mask pattern;
removing the damage region; and
patterning the conductive layer to form an n-MOS transistor gate and a p-MOS transistor gate.

2. The method of claim 1, wherein in the removing of the damage region, the damage region is removed so that the conductive layer in the n-MOS transistor region has the same height as the conductive layer in the p-MOS transistor region.

3. The method of claim 1, wherein the removing of the damage region is performed using a mixed solution comprising ammonium hydroxide (NH₄OH), hydrogen peroxide (H₂O₂), and pure water (H₂O).

4. The method of claim 3, wherein the mixed solution contains ammonium hydroxide (NH₄OH) in a range of 0.1 to 15 wt % and hydrogen peroxide (H₂O₂) in a range of 0.1 to 15 wt %.

5. The method of claim 1, wherein the removing of the damage region is performed at a temperature range of 50° C. to 90° C.

6. The method of claim 1, wherein the conductive layer comprises polysilicon.

7. The method of claim 1, wherein after forming the n-MOS transistor gate and the p-MOS transistor gate, further comprising washing the semiconductor layer on which the n-MOS transistor gate and the p-MOS transistor gate are formed using a washing solution having a fluoric acid.

8. The method of claim 1, wherein, before forming the n-MOS transistor gate and the p-MOS transistor gate, further comprising forming an anti-reflection layer on the conductive layer.

9. The method of claim 1, wherein, after forming the conductive layer on the insulation layer, further comprising forming a buffer insulation layer on the conductive layer.

10. A method of manufacturing a complementary metal-oxide semiconductor (CMOS) transistor, the method comprising:
forming a semiconductor layer in which an n-MOS transistor region and a p-MOS transistor region are defined;
forming an insulation layer on the semiconductor layer;
forming a conductive layer on the insulation layer;
forming a buffer insulation layer on the conductive layer;
forming a mask pattern exposing the n-MOS transistor region, on the conductive layer;
implanting impurities in the conductive layer of the n-MOS transistor region using the mask pattern as a mask to form a damage region in an upper portion of the conductive layer;
removing the mask pattern and the buffer insulation layer;
removing the damage region;
forming an anti-reflection layer on the conductive layer; and
patterning the conductive layer to form an n-MOS transistor gate and a p-MOS transistor gate.
